(19) United States
(12) Patent Application Publication
(10) Pub. No.: US 2026/0353574 A1
(43) Pub. Date: Nov. 5, 2026

(54) DISPLAY MODULE AND DISPLAY DEVICE

(71) Applicants: Xiamen Tianma Display Technology Co., Ltd., Xiamen (CN); Wuhan Tianma Microelectronics Co., Ltd., Wuhan (CN)

(72) Inventors: Lei Wang, Xiamen (CN); Guofeng Zhang, Xiamen (CN); Hankun Cai, Xiamen (CN); Xiaolong Zhu, Xiamen (CN); Yongqiang Han, Xiamen (CN); Yingning Wei, Xiamen (CN); Zhiwei Wang, Xiamen (CN)

(73) Assignees: Xiamen Tianma Display Technology Co., Ltd., Xiamen (CN); Wuhan Tianma Microelectronics Co., Ltd., Wuhan (CN)

(21) Appl. No.: 19/710,652

(22) Filed: Jun. 17, 2026

(30) Foreign Application Priority Data
Dec. 10, 2025 (CN) 202511860535.0

(51) Int. Cl. H05K 5/02

(52) U.S. Cl. CPC H05K 5/02

(57) ABSTRACT

Provided are a display module and a display device. The display module includes a curved display region. The curved display region includes a non-linear edge. The display module further includes a display panel and a support structure disposed in a stacked manner. The support structure is located on a non-light-emitting side of the display panel. The support structure includes a first support layer and a second support layer disposed in a stacked manner. The Young's modulus of the second support layer is greater than the Young's modulus of the first support layer. The at least second support layer is provided with at least one opening at the non-linear edge. The opening is disposed to extent through the second support layer in a thickness direction of the display module.

### CROSS-REFERENCE TO RELATED APPLICATION

This application claims priority to Chinese Patent Application No. 2025118605350, filed with the China National Intellectual Property Administration (CNIPA) on Dec. 10, 2025, the disclosure of which is incorporated herein by reference in its entirety.

### TECHNICAL FIELD

The present application relates to the technical field of display panels, and in particular, to a display module and a display device.

### BACKGROUND

With the continuous development of display technology, display modules have been widely applied in people's production and life. Furthermore, a display module including a curved display screen is becoming increasingly widespread in application scenarios and is widely favored by users. The display module includes multiple film layer structures disposed in a stacked manner, and wrinkling is likely to occur at the edge of the curved display screen due to the stacking arrangement of film layers, thereby reducing the overall display effect of the display module.

### SUMMARY

An embodiment of the present application provides a display module and a display device. At least one opening is disposed in a support layer that has a relatively large Young's modulus and is located in a support structure in the display module, which can effectively alleviate the stress generated in the display module, improve the structural stability of the display module in a curved display region, and enhance the reliability of the display module.

In a first aspect, an embodiment of the present application provides a display module. The display module includes a curved display region. The curved display region includes a non-linear edge. The display module further includes a display panel and a support structure disposed in a stacked manner. The support structure is located on a non-light-emitting side of the display panel. The support structure includes a first support layer and a second support layer disposed in a stacked manner. A Young's modulus of the second support layer is greater than a Young's modulus of the first support layer. At least the second support layer is provided with at least one opening at the non-linear edge. The at least one opening extends through the second support layer in a thickness direction of the display module.

In a second aspect, an embodiment of the present application provides a display device. The display device includes the display module in the first aspect.

As described above, the embodiment of the present application provides the display module. The display module includes the curved display region. The arc-shaped structure of the display module is embodied by the non-linear edge included in the curved display region. The display module further includes the display panel and the support structure disposed in a stacked manner. The display panel is configured to implement the display function of the display panel, and the support structure is configured to support the display panel and maintain the overall structural stability of the display module. Further, the support structure includes the first support layer and the second support layer disposed in a stacked manner. The Young's modulus of the first support layer is lower than the Young's modulus of the second support layer; that is, the film layer hardness of the second support layer is greater than the film layer hardness of the first support layer. In an embodiment, at least the second support layer is provided with the at least one opening at the non-linear edge, and the at least one opening extends through the second support layer. The provision of the opening can effectively alleviate the stress generated in the display module, avoid wrinkles and the like from occurring in the curved display region of the display module, improve the structural stability of the display module in the curved display region, and enhance the reliability of the display module.

### BRIEF DESCRIPTION OF DRAWINGS

In order to clearly illustrate technical solutions of embodiments of the present application, drawings of the embodiments of the present application will be briefly described below. Obviously, the drawings in the following description merely depict some embodiments of the present application, and other drawings may also be obtained by those of ordinary skill in the art without needing creative efforts according to the contents of the embodiments of the present application and these drawings.

FIG. 1 is a schematic structural view of a display module according to an embodiment of the present application;

FIG. 2 is a first schematic sectional view taken along a section line A-A′ of FIG. 1;

FIG. 3 is a second schematic sectional view taken along a section line A-A′ of FIG. 1;

FIG. 4 is an enlarged schematic view of a second support layer in a curved display region of FIG. 3;

FIG. 5 is a schematic sectional view taken along a section line B-B′ of FIG. 4;

FIG. 6 is another enlarged schematic view of a second support layer in a curved display region of FIG. 3;

FIG. 7 is still another enlarged schematic view of a second support layer in a curved display region of FIG. 3;

FIG. 8 is still another enlarged schematic view of a second support layer in a curved display region of FIG. 3;

FIG. 9 is still another enlarged schematic view of a second support layer in a curved display region of FIG. 3;

FIG. 10 is still another enlarged schematic view of a second support layer in a curved display region of FIG. 3;

FIG. 11 is still another enlarged schematic view of a second support layer in a curved display region of FIG. 3;

FIG. 12 is still another enlarged schematic view of a second support layer in a curved display region of FIG. 3;

FIG. 13 is still another enlarged schematic view of a second support layer in a curved display region of FIG. 3;

FIG. 14 is still another enlarged schematic view of a second support layer in a curved display region of FIG. 3;

FIG. 15 is an enlarged schematic view of a curved display region of FIG. 1;

FIG. 16 is a schematic sectional view taken along a section line C-C′ of FIG. 15;

FIG. 17 is still another enlarged schematic view of a second support layer in a Curved Display Region of FIG. 3;

FIG. 18 is a schematic sectional view taken along a section line D-D′ of FIG. 17;

FIG. 19 is still another enlarged schematic view of a second support layer in a curved display region of FIG. 3;

FIG. 20 is a schematic sectional view taken along a section line E-E′ of FIG. 19;

FIG. 21 is still another enlarged schematic view of a second support layer in a curved display region of FIG. 3;

FIG. 22 is still another enlarged schematic view of a second support layer in a curved display region of FIG. 3;

FIG. 23 is a schematic structural view of another display module according to an embodiment of the present application;

FIG. 24 is an enlarged schematic view of a second support layer in a first curved display region of FIG. 23;

FIG. 25 is an enlarged schematic view of a second support layer in a second curved display region of FIG. 23;

FIG. 26 is a schematic sectional view taken along a section line F-F′ of FIG. 15; and

FIG. 27 is a schematic structural view of a display device according to an embodiment of the present application.

### DETAILED DESCRIPTION

The present application will be further described in detail in conjunction with the drawings and embodiments below. It is to be understood that the specific embodiments described herein are merely used for explaining the present application and are not intended to limit the present application. It is also to be noted that, for ease of description, only some, but not all, of the structures related to the present application are shown in the drawings.

In the description of the present application, unless otherwise expressly specified and limited, the term “connected to each other”, “connected”, or “fixed” is to be construed in a broad sense, for example, as securely connected, detachably connected, or integrated; mechanically connected or electrically connected; directly connected to each other, indirectly connected to each other via an intermediary, internal connection between two elements, or interaction between two elements. For those of ordinary skill in the art, specific meanings of the preceding terms in the present application may be understood based on specific situations.

In the present application, unless otherwise expressly specified and limited, a first feature being “on” or “under” a second feature may include the first feature and the second feature being in direct contact, or may include the first feature and the second feature not being in direct contact but being in contact with each other through an additional feature therebetween. Moreover, the first feature being “on”, “above” or “over” the second feature includes the first feature being directly on, above or over and obliquely on, above or over the second feature, or simply indicates that the first feature is at a higher level than the second feature. The first feature being “under”, “below” or “underneath” the second feature includes the first feature being directly under, below or underneath and obliquely under, below or underneath the second feature, or simply represents that the first feature is at a lower level than the second feature.

In the description of this embodiment, the orientation or position relationships indicated by terms “above”, “below”, “right”, and the like are based on the orientation or position relationships shown in the drawings, merely for ease of description and simplifying an operation, these relationships do not indicate or imply that the referred device or element has a specific orientation and is constructed and operated in a specific orientation, and thus it is not to be construed as limiting the present application. In addition, the terms “first” and “second” are used only to distinguish between descriptions and have no special meaning.

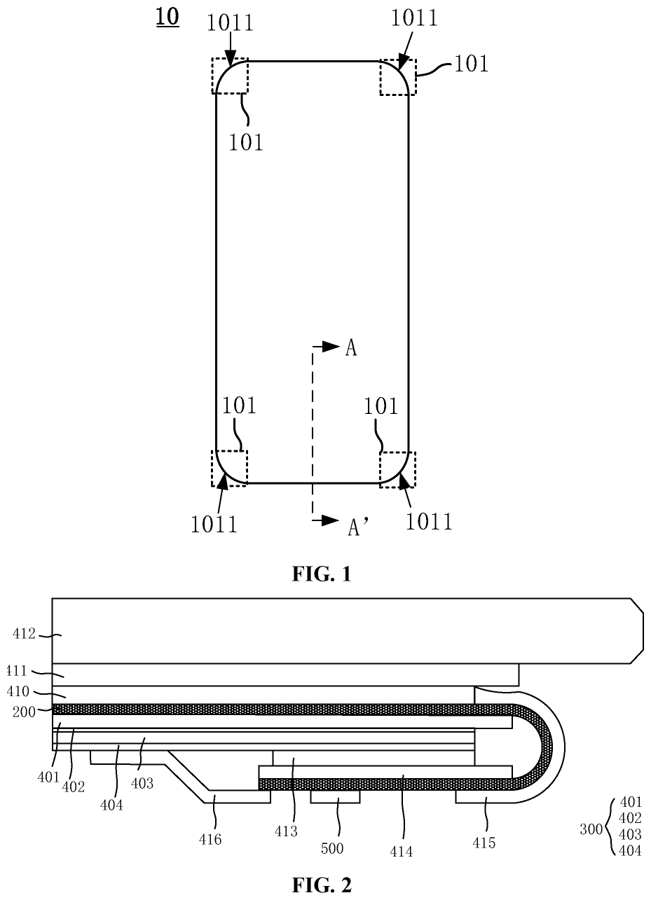

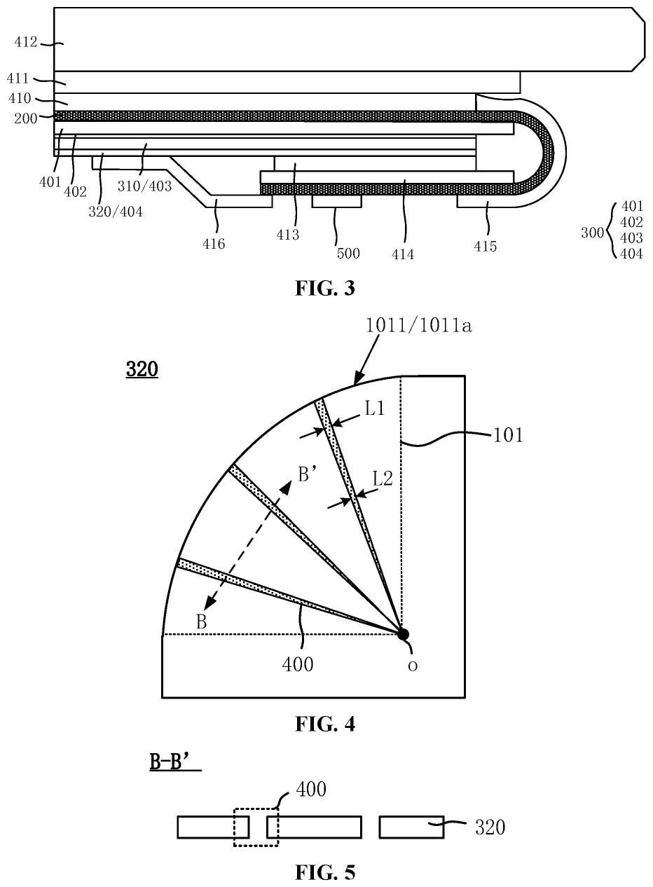

FIG. 1 is a schematic structural view of a display module according to an embodiment of the present application, FIG. 2 is a first schematic sectional view taken along a section line A-A′ of FIG. 1, FIG. 3 is a second schematic sectional view taken along a section line A-A′ of FIG. 1, FIG. 4 is an enlarged schematic view of a second support layer in a curved display region of FIG. 3, and FIG. 5 is a schematic sectional view taken along a section line B-B′ of FIG. 4. Referring to FIGS. 1 to 5, the present application provides a display module 10. The display module 10 includes a curved display region 101. The curved display region 101 includes a non-linear edge 1011. The display module 10 further includes a display panel 200 and a support structure 300 disposed in a stacked manner. The support structure 300 is located on a non-light-emitting side of the display panel 200. The support structure 300 includes a first support layer 310 and a second support layer 320 disposed in a stacked manner, and the Young's modulus of the second support layer 320 is greater than the Young's modulus of the first support layer 310. At least the second support layer 320 is provided with at least one opening 400 at the non-linear edge 1011. The opening 400 extends through the second support layer 320 in a thickness direction of the display module 10.

In an embodiment, referring to FIG. 1, the display module 10 includes the curved display region 101. The curved display region 101 includes the non-linear edge 1011, that is, the display module 10 is a curved display structure with a curved line edge, which can provide a better visual effect. The set number of curved display regions 101 in the display module 10 is varied. FIG. 1 illustrates, by way of example, that the display module 10 includes four curved display regions 101, and the set number of curved display regions 101 in the display module 10 may be adaptively adjusted, which is not specifically limited in embodiments of the present application.

Referring to FIGS. 1 and 2, the display module 10 further includes a display panel 200. The display panel 200 includes a light-emitting element (not specifically shown in the drawings) and a driver circuit (not specifically shown in the drawings) electrically connected to the light-emitting element. The driver circuit drives the light-emitting element to emit light for display, so as to achieve the display effect of the display panel 200 and further ensure the display function of the display module 10. Optionally, the arrangement types of the light-emitting element in the display panel 200 and the driver circuit in the display panel 200 are not in an embodiment limited in the embodiments of the present application and may be adaptively adjusted according to actual requirements.

Further, referring to FIGS. 1 and 2, the display module 10 further includes a support structure 300 located on the non-light-emitting side of the display panel 200. The support structure 300 is provided for supporting the display panel 200 and other film layer structures in the display module 10, so as to ensure the overall structural stability of the display module 10. In an embodiment, referring to FIG. 2, the support structure 300 includes multiple film layer structures disposed in a stacked manner, such as an inorganic support layer 401, an adhesive layer 402, a foam 403, a metal support layer 404, and the specific film layer structure of the support structure 300 may be adaptively adjusted according to different display modules 10, which is not in an embodiment limited in the embodiments of the present application.

The Young's moduli of multiple film layer structures in the support structure 300 are different; that is, different film layers in the support structure 300 have different hardness. Referring to FIGS. 2 and 3, the support structure 300 includes a first support layer 310 and a second support layer 320, and the Young's modulus of the second support layer 320 is greater than the Young's modulus of the first support layer 310; that is, the hardness of the second support layer 320 is greater than the hardness of the first support layer 310. Exemplarily, referring to FIGS. 2 and 3, the first support layer 310 and the second support layer 320 may be any two film layers among the inorganic support layer 401, the adhesive layer 402, the foam 403, and the metal support layer 404, as long as the hardness of the first support layer 310 is less than the hardness of the second support layer 320. Exemplarily, referring to FIG. 3, the first support layer 310 may be the foam 403, and the second support layer 320 may be the metal support layer 404. It is to be noted that FIG. 3 merely illustrates one arrangement condition of the first support layer 310 and the second support layer 320, and the first support layer 310 and the second support layer 320 may be other film layer structures in the support film layer 300, which will not be enumerated one by one herein.

Further, referring to FIGS. 2 to 5, in the support structure 300, multiple openings 400 are disposed at least in the second support layer 320, and the openings 400 are configured to extent through the second support layer 320. That is, the openings 400 are disposed in the film layer with a higher Young's modulus, which can timely release the stress generated by the film layer and the acting force transmitted to the film layer from other film layers, and avoid the stress from affecting and damaging the film layer structure. In an embodiment, the second support layer 320 is provided with at least one opening 400 at the non-linear edge 1011, that is, the opening 400 is disposed in the curved display region 101 and disposed at the non-linear edge 1011. In the display module 10, the non-linear edge 1011 of the curved display region 101 is subjected to stress generated from multiple directions; therefore, wrinkles are more likely to occur in the curved display region 101 due to untimely stress release. Providing the opening 400 at the non-linear edge 1011 can prevent the generated stress from causing wrinkles and the like in the curved display region 101 of the display module 10, thereby better ensuring the structural stability of the display module 10 and improving the reliability of the display module 10. Further, the second support layer 320 may be provided with multiple openings 400, and different openings 400 may be adjusted in a differentiated manner. As shown in FIG. 4, FIG. 4 illustrates, by way of example, that the second support layer 320 is provided with three openings 400 at one curved display region 101. The specific setting number of openings 400 may be adaptively adjusted according to actual requirements, which is not specifically limited in the present application. In other words, in the support structure 300, the film layer structure with a higher Young's modulus may be subjected to opening processing, and the opening 400 is disposed at the non-linear edge 1011 of the curved display region 101. This arrangement can effectively avoid film layer wrinkles occurring in the curved display region 101 of the display module 10, so as to ensure the overall structural stability of the display module 10. It is to be noted that, in order to clearly show the openings 400 disposed on the second support layer 320 in FIG. 4, the openings 400 are filled with patterns in FIG. 4.

Optionally, referring to FIGS. 2 and 3, the display module 10 further includes a polarizer 410, an optical adhesive 411, and a cover plate 412. The polarizer 410 is configured to prevent light incident on the display module 10 from exiting the display module 10 again, thereby reducing interference of ambient light to light emitted by the display module 10 itself, and further ensuring the overall display effect of the display module 10. The optical adhesive 411 is used for bonding the overall structure to ensure the overall structural stability of the display module 10. The cover plate 412 serves to protect the structure of the display module 10, so as to ensure the reliability of the display module 10. Other film layers may be adaptively added for different display modules 10, which will not be described in detail one by one in the embodiments of the present application.

Further, referring to FIGS. 2 and 3, the display module 10 further includes a driver chip 500 electrically connected to the display panel 200. The driver chip 500 is configured to supply relevant signals to the display panel 200 so as to ensure the normal display function of the display panel 200. Referring to FIG. 2 and FIG. 3, one end of the display panel 200 in the display module 10 may be bent to the non-light-emitting side of the display module 10, and the driver chip 500 is accordingly disposed on the non-light-emitting side of the display module 10. In this way, the area of the lower bezel of the display module 10 can be reduced, and the screen-to-body ratio of the display module 10 is improved. Further, referring to FIG. 2 and FIG. 3, the display module 10 further includes a flexible circuit board 416. Signals provided by the driver chip 500 and signals provided by the flexible circuit board 416 are transmitted to the display panel 200 through bonding terminals (not specifically shown in the drawings), so as to achieve the display function of the display panel 200. Further, referring to FIG. 2 and FIG. 3, the display module 10 further includes a protective layer 415. A region of the display panel 200 covered by the protective layer 415 may be regarded as a bent region of the display panel 200. The protective layer 415 is configured to protect the display panel 200 in the bent region, thereby ensuring the structural stability of the display module 10. On a side of the foam 403 facing away from the display panel 200, a double-sided adhesive tape 413 and an inorganic support layer 414 are further provided. Both the inorganic support layer 414 and the inorganic support layer 401 are configured to support the display panel 200 so as to ensure the structural stability of the display panel 200. The double-sided adhesive tape 413 is configured to fix the metal support layer 404 and the inorganic support layer 414, and also serves to ensure the structural stability of the display module 10.

In summary, the embodiments of the present application provide the display module. The display module includes the display panel and the support structure disposed in a stacked manner. The display panel is configured to implement the display function of the display panel, and the support structure is configured to support the display panel and ensure the overall structural stability of the display module. In an embodiment, the support structure includes the first support layer and the second support layer, which are disposed in a stacked manner and have different Young's moduli. The at least one opening is disposed in the second support layer with the higher Young's modulus, and the opening is disposed at the non-linear edge. The additional provision of the opening can effectively alleviate the stress generated in the display module, avoid wrinkles and the like from occurring in the curved display region of the display module, improve the structural stability of the display module in the curved display region, and enhance the reliability of the display module.

With continued reference to FIG. 4, the non-linear edge 1011 includes an arc-shaped edge 1011a. At least part of the at least one opening 400 extends to a circle center o of the arc-shaped edge 1011a in a radial direction of the arc-shaped edge 1011a.

In an embodiment, referring to FIG. 4, the non-linear edge 1011 includes the arc-shaped edge 1011a, and at least part of the openings 400 located at the arc-shaped edge 1011a may extend to the circle center o of the circle of the arc-shaped edge 1011a. That is, the opening 400 disposed in the second support layer 320 may have a strip-shaped opening structure, and the length of the opening 400 may be a length from the arc-shaped edge 1011a to the circle center o in the radial direction of the arc-shaped edge 1011a.

Further, with reference to FIG. 4, in the present application, at least part of the openings 400 extend from the arc-shaped edge 1011a to the circle center o, which equivalently increases the length of such openings 400 in the radial direction. Consequently, stress generated at different positions in the radial direction can be effectively released, so as to better prevent the stress from affecting the structure of the display module 10 and avoid wrinkling of the display module 10.

With continued reference to FIG. 4, an opening width of the at least one opening 400 gradually decreases in a direction from the arc-shaped edge 1011a toward the circle center o.

Further, referring to FIG. 4, in the direction from the arc-shaped edge 1011a toward the circle center o, a width of the opening 400 in a direction perpendicular to the radial direction is disposed in a gradually changing manner. Reference may be made to L1 and L2 in FIG. 4, where L1>L2, and L1 and L2 are each a positive number. That is, the width of the opening 400 in the direction perpendicular to the radial direction increases closer to the arc-shaped edge 1011a, and decreases closer to the circle center o. By gradually adjusting the width of the opening 400, on one hand, stress generated within the film layer structure of the display module 10 can be better accommodated, and on the other hand, the fabrication process of the opening 400 can be better satisfied.

In an embodiment, referring to FIG. 4, the stress generated in the second support layer 320 is relatively greater closer to the arc-shaped edge 1011a and relatively smaller closer to the circle center o. In combination with the distribution variation trend of stress in the curved display region 101, the opening width of the opening 400 in the direction perpendicular to the radial direction may be adaptively adjusted, so that a favorable stress relief effect in each region of the second support layer 320 can be ensured and thus the structural stability of the second support layer 320 can be ensured. Further, the opening 400 in the second support layer 320 may be fabricated by a grooving process. In the direction from the arc-shaped edge 1011a toward the circle center o, the arrangement in which the opening width of the opening 400 in the direction perpendicular to the radial direction gradually decreases is better compatible with the grooving process, thereby enabling a simplified fabrication process of the opening 400.

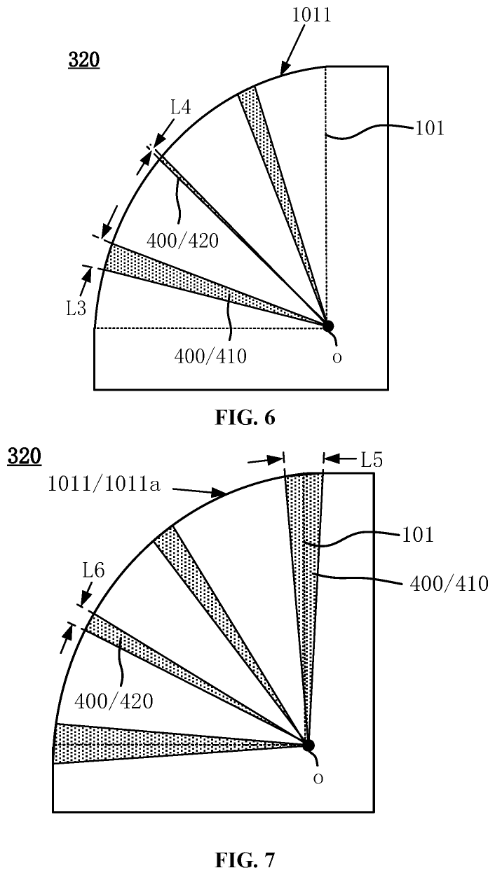

On the basis of the above embodiments, FIG. 6 is another enlarged schematic view of a second support layer in a curved display region of FIG. 3, and FIG. 7 is still another enlarged schematic view of a second support layer in a curved display region of FIG. 3. Referring to FIGS. 6 and 7, at least the second support layer 320 is provided with multiple openings 400 at the non-linear edge 1011. The multiple openings 400 include a first opening 410 and a second opening 420. An opening width of the first opening 410 at a position where the non-linear edge 1011 is located is greater than an opening width of the second opening 420 at the position where the non-linear edge 1011 is located.

Further, referring to FIGS. 6 and 7, the second support layer 320 may be provided with multiple openings 400 at the non-linear edge 1011. FIG. 6 illustrates, by way of example, that one curved display region 101 includes three openings 400, and FIG. 7 illustrates, by way of example, that one curved display region 101 includes four openings 400. Optionally, five openings 400 or more openings 400 may be disposed at one curved display region 101, and the specific setting number of openings 400 is not limited in the present application.

Further, referring to FIGS. 6 and 7, the multiple openings 400 disposed in the second support layer 320 include a first opening 410 and a second opening 420, and the first opening 410 and the second opening 420 may differ not only in arrangement positions, but also in opening widths at the non-linear edge 1011. In an embodiment, the opening width of the first opening 410 at the position where the non-linear edge 1011 is located is greater than the opening width of the second opening 420 at the position where the non-linear edge 1011 is located. Exemplarily, referring to FIG. 6, the opening width of the first opening 410 at the position where the non-linear edge 1011 is located is L3, and the opening width of the second opening 420 at the position where the non-linear edge 1011 is located is L4, where L3>L4. Referring to FIG. 7, the opening width of the first opening 410 at the position where the non-linear edge 1011 is located is L5, and the opening width of the second opening 420 at the position where the non-linear edge 1011 is located is L6, where L5>L6.

Generally speaking, different openings 400 in the second support layer 320 may be refined and adjusted in combination with different mounting positions thereof and different requirements (for example, requirements for display effects or requirements for stress relief), so as to ensure that the overall effect of the display module 10 is better.

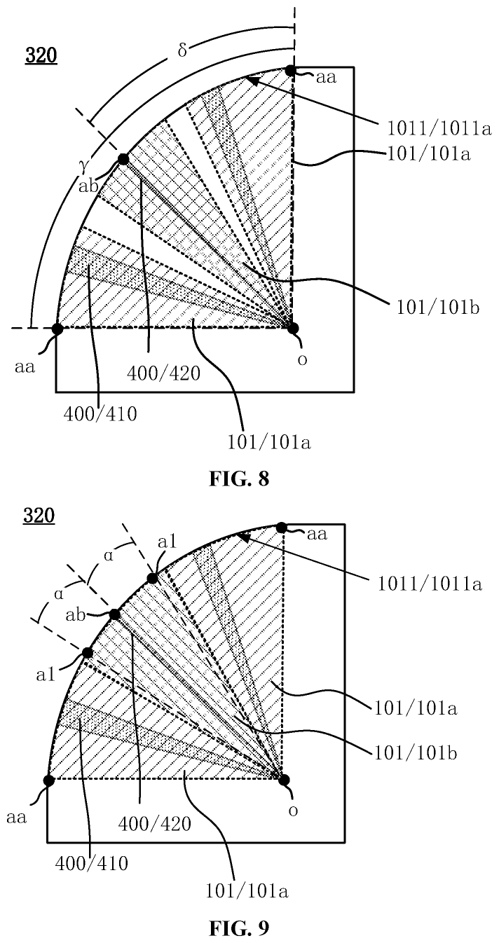

In an embodiment, FIG. 8 is still another enlarged schematic view of a second support layer in a curved display region of FIG. 3, and FIG. 9 is still another enlarged schematic view of a second support layer in a curved display region of FIG. 3. Referring to FIGS. 8 and 9, the non-linear edge 1011 includes an arc-shaped edge 1011a. The arc-shaped edge 1011a includes an arc-shaped starting point aa and an arc-shaped midpoint ab. A central angle corresponding to the arc-shaped edge 1011a is γ, and a central angle corresponding to an arc segment between the arc-shaped midpoint ab and the arc-shaped starting point aa is δ, where δ=γ/2. The curved display region 101 includes a first curved sub-display region 101a and a second curved sub-display region 101b. The first curved sub-display region 101a includes the arc-shaped starting point aa. The second curved sub-display region 101b includes the arc-shaped midpoint ab. The first opening 410 is located in the first curved sub-display region 101a, and the second opening 420 is located in the second curved sub-display region 101b.

In an embodiment, referring to FIGS. 8 and 9, the non-linear edge 1011 includes the arc-shaped edge 1011a, and the arc-shaped edge 1011a includes the arc-shaped starting point aa and the arc-shaped midpoint ab. The arc-shaped starting point aa may be understood as the positions of two end points of the arc-shaped edge 1011a, and the arc-shaped midpoint ab may be understood as the center point of the entire arc-shaped edge 1011a. Further, in an embodiment referring to FIG. 8, the central angle corresponding to the arc-shaped edge 1011a is γ, and the central angle corresponding to the arc segment between the arc-shaped midpoint ab and the arc-shaped starting point aa is δ, where γ and δ satisfy that δ=γ/2. Exemplarily, the central angle δ corresponding to the arc segment between the arc-shaped midpoint ab and the arc-shaped starting point aa may be 45°, and the central angle γ corresponding to the arc-shaped edge 1011a may be 90°.

Further, referring to FIGS. 8 and 9, the curved display region 101 includes the first curved sub-display region 101a and the second curved sub-display region 101b. The first curved sub-display region 101a includes the arc-shaped starting point aa. The second curved sub-display region 101b includes the arc-shaped midpoint ab. The first curved sub-display region 101a may be understood as a region close to the edge of the curved display region 101, and the second curved sub-display region 101b may be understood as a region at the center of the curved display region 101. In FIGS. 8 and 9, the first curved sub-display region 101a and the second curved sub-display region 101b are demarcated and illustrated by means of filling patterns. Optionally, referring to FIG. 8, the first curved sub-display region 101a and the second curved sub-display region 101b may be disposed at intervals, and referring to FIG. 9, the first curved sub-display region 101a and the second curved sub-display region 101b may be disposed adjacent to each other.

Further, the first opening 410 is located in the first curved sub-display region 101a, the second opening 420 is located in the second curved sub-display region 101b, the second opening 420 is closer to the center of the curved display region 101 than the first opening 410, and the opening width of the first opening 410 at the position where the non-linear edge 1011 is located is greater than the opening width of the second opening 420 at the position where the non-linear edge 1011 is located. That is, at the center of the curved display region 101, the opening width of the second opening 420 at the position where the non-linear edge 1011 is relatively small. This arrangement allows a larger area of the second support layer 320 to be retained in a central region of the curved display region 101, thereby optimizing the overall heat conduction and electrostatic conduction effects of the display module 10 in this region. Exemplarily, the second support layer 320 is a metal support layer 404 capable of conducting heat and static electricity, and the second openings 420 with a relatively small opening width is disposed in the second curved sub-display region 101b, so that a relatively large area of the metal support layer 404 can be retained at the center of the curved display region 101, thereby ensuring the heat dissipation effect and static conduction performance of the display module 10 in the curved display region 101 and further ensuring the display effect of the display module 10.

With continued reference to FIGS. 8 and 9, the second curved sub-display region 101b further includes a first edge point a1 located on the arc-shaped edge 1011a. A central angle α corresponding to an arc segment between the first edge point a1 and the arc-shaped midpoint ab satisfies 0°<α≤15°.

Further, in an embodiment referring to FIG. 9, the second curved sub-display region 101b further includes the first edge point a1 located on the arc-shaped edge 1011a, and the central angle α corresponding to the arc segment between the first edge point a1 and the arc-shaped midpoint ab may satisfy 0°<α≤15°, for example, α may be any one of 0°, 10°, or 15°, which is not in an embodiment limited in the embodiments of the present application.

Referring to FIG. 9, the first edge point a1 may be located on two sides of the arc-shaped midpoint ab on the arc-shaped edge 1011a. Therefore, by defining the central angle α corresponding to the arc segment between the first edge point a1 and the arc-shaped midpoint ab, the range value of the central angle corresponding to the arc segment of the second curved sub-display region 101b is determined accordingly. Exemplarily, when α is selected as 15°, the central angle corresponding to the arc segment of the second curved sub-display region 101b in the central region may be 30°; and when α is selected as 10°, the central angle corresponding to the arc segment of the second curved sub-display region 101b may be 20°. The specific angle value may be adaptively adjusted according to actual requirements, which is not specifically limited in the present application.

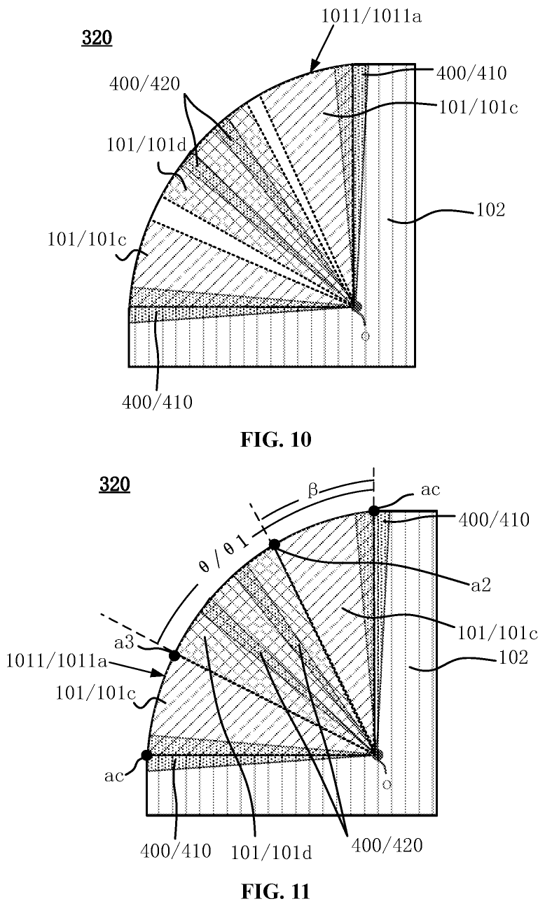

FIG. 10 is still another enlarged schematic view of a second support layer in a curved display region of FIG. 3, and FIG. 11 is still another enlarged schematic view of a second support layer in a curved display region of FIG. 3. Referring to FIGS. 10 and 11, the display module 10 further includes a planar display region 102. The planar display region 102 is located on at least one side of the curved display region 101, and the curved display region 101 includes a third curved sub-display region 101c and a fourth curved sub-display region 101d. The third curved sub-display region 101c is located on a side of the fourth curved sub-display region 101d facing the planar display region 102. A part of the first opening 410 is disposed in the third curved sub-display region 101c, the remaining part of the first opening 410 is disposed in the planar display region 102, and the second opening 420 is disposed in the fourth curved sub-display region 101d.

In an embodiment, referring to FIGS. 10 and 11, the display module 10 further includes the planar display region 102, and the planar display region 102 is located on at least one side of the curved display region 101. In FIG. 10 and FIG. 11, the planar display region 102 and the curved display region 101 are demarcated by different filling patterns.

Further, referring to FIGS. 10 and 11, the curved display region 101 includes a third curved sub-display region 101c and a fourth curved sub-display region 101d. The third curved sub-display region 101c is closer to the planar display region 102 than the fourth curved sub-display region 101d, that is, the third curved sub-display region 101c is disposed at an edge region of the curved display region 101, and an edge of the third curved sub-display region 101c facing away from the fourth curved sub-display region 101d is disposed to overlap with the edge of the planar display region 102. The fourth curved sub-display region 101d is disposed in the middle region of the curved display region 101. Optionally, referring to FIG. 10, the third curved sub-display region 101c and the fourth curved sub-display region 101d may be disposed at intervals, and referring to FIG. 11, the third curved sub-display region 101c and the fourth curved sub-display region 101d may be disposed adjacent to each other.

Further, the part of the first opening 410 is disposed in the third curved sub-display region 101c, and the remaining part of the first opening 410 is disposed in the planar display region 102. This can be understood that in the thickness direction of the display module 10, the first opening 410 overlaps the third curved sub-display region 101c and the planar display region 102. The second opening 420 is located in the fourth curved sub-display region 101d. Therefore, near the center of the curved display region 101, the opening width of the second opening 420 at the position where the non-linear edge 1011 is located is relatively small. This enables a larger area of the metal support layer 404 to be retained at the center of the curved display region 101, thereby improving the heat dissipation performance, electrostatic conduction performance, and the like of the display module 10 in the curved display region 101, and further ensuring the display effect of the display module 10. In the display module 10, the stress generated at the boundary arrangement region between the curved display region 101 and the planar display region 102 is greater than the stress generated inside the curved display region 101, or slightly greater than the stress generated inside the planar display region 102. Therefore, the first opening 410 with a relatively large opening width is disposed at the alternating arrangement region of the curved display region 101 and the planar display region 102, so as to achieve an excellent stress relief effect at this position, further ensure the structural stability of the display module 10, and prevent wrinkles from occurring in the film layer structure.

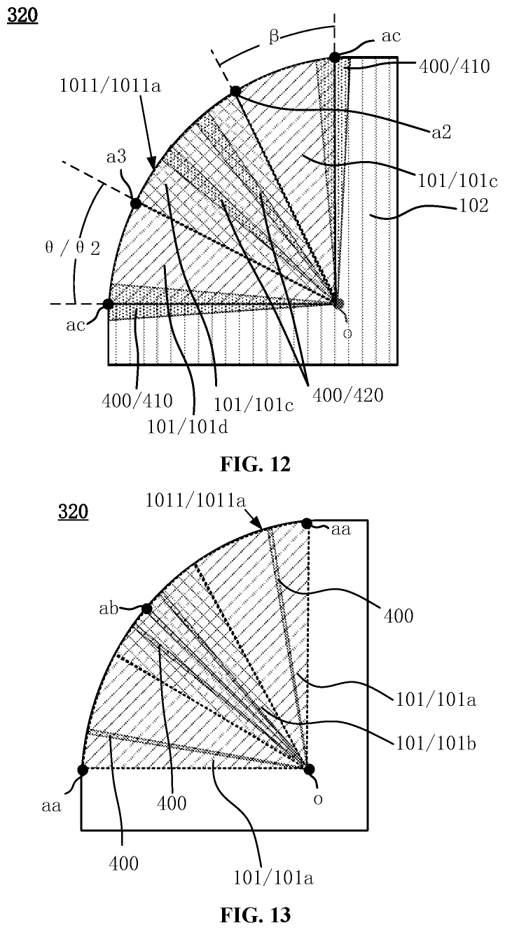

FIG. 12 is still another enlarged schematic view of a second support layer in a curved display region of FIG. 3. With continued reference to FIGS. 11 and 12, the non-linear edge 1011 includes an arc-shaped edge 1011a. The arc-shaped edge 1011a includes an arc-shaped starting point ac on the side close to the planar display region 102. The third curved sub-display region 101c includes a second edge point a2 located on the arc-shaped edge 1011a. The fourth curved sub-display region 101d includes a third edge point a3 located on the arc-shaped edge 1011a. A central angle β corresponding to an arc segment between the second edge point a2 and the arc-shaped starting point ac satisfies 0°<β≤15°, and a central angle θ corresponding to an arc segment between the third edge point a3 and the arc-shaped starting point ac satisfies 30°≤θ≤60°.

In an embodiment referring to FIGS. 11 and 12, the non-linear edge 1011 includes the arc-shaped edge 1011a, and the arc-shaped edge 1011a includes the arc-shaped starting point ac, one side of the arc-shaped starting point ac is the planar display region 102, and the other side of the arc-shaped starting point ac is the curved display region 101.

Further, referring to FIGS. 11 and 12, the third curved sub-display region 101c includes the second edge point a2 located on the arc-shaped edge 1011a, and the central angle β corresponding to an arc segment between the second edge point a2 and the arc-shaped starting point ac satisfies 0°<β≤15°, and for example, β may be any one of 0°, 10°, or 15°. The central angle β can be understood as a range value of a central angle corresponding to an arc segment of the third curved sub-display region 101c. Exemplarily, if the central angle β corresponding to an arc segment between the second edge point a2 and the arc-shaped starting point ac is selected as 15°, the central angle corresponding to the arc segment of the third curved sub-display region 101c may be 15°; and if the central angle β corresponding to an arc segment between the second edge point a2 and the arc-shaped starting point ac is selected as 10°, the central angle corresponding to the arc segment of the third curved sub-display region 101c may be 10°.

Further, referring to FIGS. 11 and 12, the fourth curved sub-display region 101d includes the third edge point a3 located on the arc-shaped edge 1011a, and the central angle θ corresponding to the arc segment between the third edge point a3 and the arc-shaped starting point ac satisfies 30°≤θ≤60°, and for example, θ may be any one of 30°, 40°, 50°, or 60°. In an embodiment, referring to FIG. 11, the central angle θ (denoted by θ1 in FIG. 11) corresponding to the arc segment between the third edge point a3 and the arc-shaped starting point ac can be understood as a central angle θ corresponding to a longest arc segment between one edge trace of the third curved sub-display region 101c and the arc-shaped starting point ac. Exemplarily, when the central angle θ is selected as 60°, the central angle corresponding to the longest arc segment between one edge trace of the third curved sub-display region 101c and the arc-shaped starting point ac may be 60°. Further, if the central angle β corresponding to an arc segment between the second edge point a2 and the arc-shaped starting point ac is selected as 10°, a central angle corresponding to an arc segment of the fourth curved sub-display region 101d may be 50°(a difference value between the central angle θ and the central angle β). In an embodiment, referring to FIG. 12, the central angle θ (denoted by θ2 in FIG. 12) corresponding to the arc segment between the third edge point a3 and the arc-shaped starting point ac can be understood as a central angle θ corresponding to a shortest arc segment between one edge trace of the third curved sub-display region 101c and the arc-shaped starting point ac. Exemplarily, when the central angle θ is selected as 30°, the central angle corresponding to the longest arc segment between one edge trace of the third curved sub-display region 101c and the arc-shaped starting point ac may be 30°. The specific angle values of the central angle β and the central angle θ can be adaptively adjusted according to actual requirements, which is not specifically limited in the present application.

FIG. 13 is still another enlarged schematic view of a second support layer in a curved display region of FIG. 3. Referring to FIG. 13, at least the second support layer 320 is provided with multiple openings 400 at the non-linear edge 1011. The non-linear edge 1011 includes an arc-shaped edge 1011a. The arc-shaped edge 1011a includes an arc-shaped starting point aa and an arc-shaped midpoint ab. A central angle corresponding to the arc-shaped edge 1011a is γ, and a central angle corresponding to an arc segment between the arc-shaped midpoint ab and the arc-shaped starting point aa is δ, where δ=γ/2. The curved display region 101 includes a first curved sub-display region 101a and a second curved sub-display region 101b. The first curved sub-display region 101a includes the arc-shaped starting point aa. The second curved sub-display region 101b includes the arc-shaped midpoint ab. A distribution density of the openings 400 located in the second curved sub-display region 101b is greater than a distribution density of the openings 400 located in the first curved sub-display region 101a.

Further, as shown in FIG. 13, the curved display region 101 includes the first curved sub-display region 101a and the second curved sub-display region 101b. Multiple openings 400 are disposed in the first curved sub-display region 101a and the second curved sub-display region 101b, which can effectively relieve and release the stress at the curved display region 101 in the display module 10, and ensure the overall structural stability of the display module 10.

The second curved sub-display region 101b is closer to the edge region of the curved display region 101 than the first curved sub-display region 101a. Therefore, according to the positional difference between the first curved sub-display region 101a and the second curved sub-display region 101b, the multiple openings 400 distributed in the first curved sub-display region 101a and the second curved sub-display region 101b can be adjusted more finely, so as to further ensure the stress-releasing effect and better ensure the structural stability of the display module 10.

In an embodiment, in the curved display region 101, if the stress near the central region of the curved display region 101 cannot be released in a timely manner, wrinkles of the film layer will become more obvious, which affects the structural stability of the display module 10. Therefore, the distribution density of the openings 400 near the central region of the curved display region 101 is increased, so that the interference of stress in the curved display region 101 on the film layer structure can be effectively alleviated. In an embodiment, the distribution density of the openings 400 in the second curved sub-display region 101b is adjusted to be higher than the distribution density of the openings 400 in the first curved sub-display region 101a. Exemplarily, referring to FIG. 13, three openings 400 are disposed in the second curved sub-display region 101b, and one opening 400 is disposed in each first curved sub-display region 101a, so as to adjust the distribution density of the openings 400.

By adjusting the distribution of the openings 400 in the first curved sub-display region 101a and the second curved sub-display region 101b, stress can be released more effectively and reliably. This improves the anti-wrinkle effect of the second support layer 320 near the arc-shaped midpoint ab, thereby ensuring the structural stability of the second support layer 320 and further ensuring the structural stability of the display module 10.

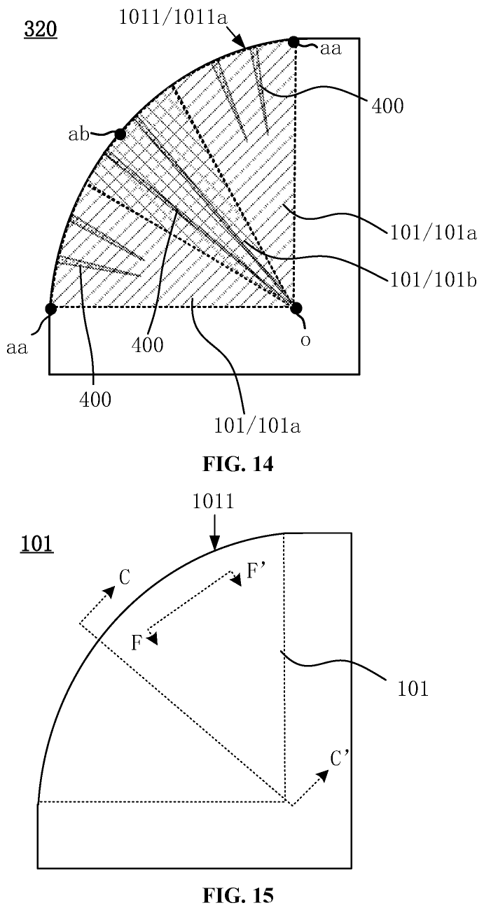

FIG. 14 is still another enlarged schematic view of a second support layer in a curved display region of FIG. 3. Referring to FIG. 14, at least the second support layer 320 is provided with multiple openings 400 at the non-linear edge 1011. The non-linear edge 1011 includes an arc-shaped edge 1011a. The arc-shaped edge 1011a includes an arc-shaped starting point aa and an arc-shaped midpoint ab. A central angle corresponding to the arc-shaped edge 1011a is γ, and a central angle corresponding to an arc segment between the arc-shaped midpoint ab and the arc-shaped starting point aa is δ, where δ=γ/2. The curved display region 101 includes a first curved sub-display region 101a and a second curved sub-display region 101b. The first curved sub-display region 101a includes the arc-shaped starting point aa. The second curved sub-display region 101b includes the arc-shaped midpoint ab. An extension length of the opening 400 located in the second curved sub-display region 101b is greater than an extension length of the opening 400 located in the first curved sub-display region 101a.

In an embodiment, in the curved display region 101, if the stress near the central region of the curved display region 101 cannot be released in a timely manner, wrinkles of the film layer will become more obvious, which affects the structural stability of the display module 10. Therefore, the extension length of the opening 400 close to the central region of the curved display region 101 is increased, so that the interference of stress in the curved display region 101 on the film layer structure can be effectively alleviated. In an embodiment, the extension length of the opening 400 in the second curved sub-display region 101b is adjusted to be greater than the extension length of the openings 400 in the first curved sub-display region 101a. Exemplarily, referring to FIG. 14, the opening 400 in the second curved sub-display region 101b extends to the circle center o, while the opening 400 disposed in each first curved sub-display region 101a does not extend to the circle center o, so as to achieve adjustment of the extension lengths of different openings 400.

By adjusting the extension lengths of the openings 400 in the first curved sub-display region 101a and the second curved sub-display region 101b, stress can be released more effectively and reliably. This improves the anti-wrinkle effect of the second support layer 320 near the arc-shaped midpoint ab, thereby ensuring the structural stability of the second support layer 320 and further ensuring the structural stability of the display module 10.

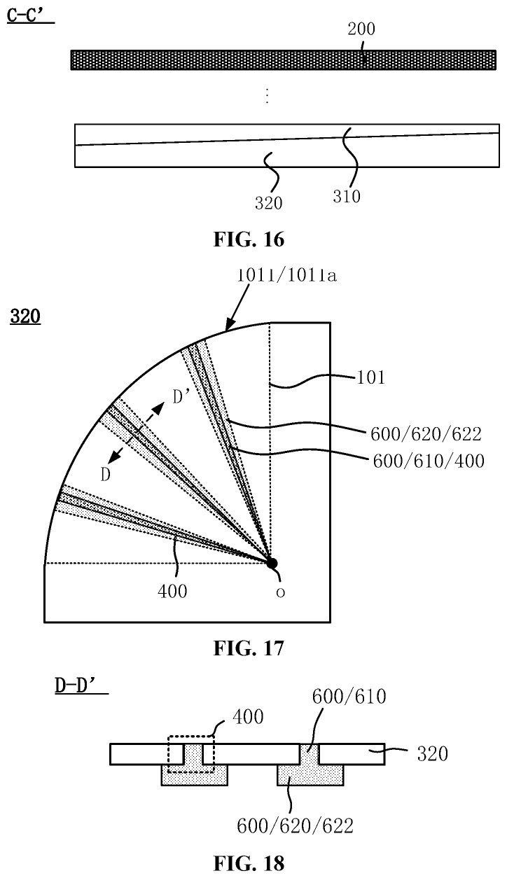

FIG. 15 is an enlarged schematic view of a curved display region of FIG. 1, and FIG. 16 is a schematic sectional view taken along a section line C-C′ of FIG. 15. Referring to FIGS. 15 and 16, the thickness of the first support layer 310 disposed in the curved display region 101 gradually decreases in a direction from a non-linear edge 1011 toward the center of the display module 10.

In an embodiment, referring to FIG. 16, the thickness of the first support layer 310 disposed in the curved display region 101 may be varied in the direction from the non-linear edge 1011 toward the center of the display module 10, so that the display module 10 can better absorb stress in the curved display region 101, and the overall structure of the display module 10 is more stable.

In an embodiment, the Young's modulus of the first support layer 310 is relatively small; that is, the hardness of the first support layer 310 is relatively small. Therefore, the structure of the first support layer 310 itself can provide a good stress absorption effect. Referring to FIG. 16, the thickness of the first support layer 310 close to the non-linear edge is greater than the thickness of the first support layer 310 close to the center of the display module 10. Therefore, the thickness of the first support layer 310 is adjusted so that the display module 10 can fully absorb the generated stress at the non-linear edge 1011 of the curved display region 101, thereby avoiding the occurrence of wrinkles at the non-linear edge 1011, and ensuring the overall structural stability.

It is to be noted that, in the support structure 300, the first support layer 310 and the second support layer 320 differ in Young's modulus. The first support layer 310 and the second support layer 320 may be selected from any two film layer structures in the support structure 300, which is not specifically limited in the present application. In FIG. 16, the first support layer 310 is located on a side of the second support layer 320 facing the display panel 200. In other embodiments, the first support layer 310 may be located on a side of the second support layer 320 facing away from the display panel 200. In FIG. 16, the first support layer 310 and the second support layer 320 are disposed adjacent to each other, and in other embodiments, other film layer structures may be disposed between the first support layer 310 and the second support layer 320, which is not in an embodiment limited in the embodiments of the present application.

With continued reference to FIGS. 15 and 16, the thickness of the second support layer 320 disposed in the curved display region 101 gradually increases in the direction from the non-linear edge 1011 toward the center of the display module 10.

Further, referring to FIG. 16, in a case where the thickness of the first support layer 310 disposed in the curved display region 101 gradually decreases in the direction from the non-linear edge 1011 toward the center of the display module 10, in order to ensure the flatness of the overall structure of the display module 10, the thickness value of the second support layer 320 may be adaptively adjusted. In an embodiment, the thickness of the first support layer 310 close to the non-linear edge is adjusted to be less than the thickness of the first support layer 310 close to the center of the display module 10. Moreover, the thickness of the second support layer 320 gradually increases in the direction from the non-linear edge 1011 toward the center of the display module 10, and such a thickness arrangement of the second support layer 320 can also match the distribution of the stresses. In an embodiment, a relatively high stress is generated at the non-linear edge 1011, and in this case, the second support layer 320 has a relatively small thickness and thus accumulates less stress. In combination with the opening disposed in the second support layer 320, an excellent stress release effect of the second support layer 320 can be achieved, thereby ensuring the overall structural stability.

FIG. 17 is still another enlarged schematic view of a second support layer in a curved display region of FIG. 3, and FIG. 18 is a schematic sectional view taken along a section line D-D′ of FIG. 17. Referring to FIGS. 17 and 18, the display module 10 further includes a filling structure 600. The filling structure 600 is configured to at least partially fill the at least one opening 400 and has a Young's modulus less than the Young's modulus of the second support layer 320.

Referring to FIGS. 17 and 18, the display module 10 further includes the filling structure 600 filled in the opening 400. The filling structure 600 has a Young's modulus less than the Young's modulus of the second support layer 320. By adding the filling structure 600, the overall structural stability and reliability of the display module 10 can be further improved.

In an embodiment, the filling structure 600 filled in the opening 400 can block the opening 400 to prevent other particles (such as some particles generated during the manufacturing process) from being transported to the opening 400, which may affect the structural stability of the second support layer 320, cause display defects of the curved display region 101, and the like. The filling structure 600 filled in the opening 400 can also ensure that the structure of the opening 400 and the adjacent region is flatter, thereby improving the overall flatness of the display module 10. The Young's modulus of the filling structure 600 filled in the opening 400 is less than the Young's modulus of the second support layer 320; therefore, the stress can be effectively released at the opening 400, thereby ensuring the structural stability of the display module 10.

With continued reference to FIGS. 17 and 18, the filling structure 600 includes a first filling section 610 and a second filling section 620 connected to each other. The first filling section 610 is configured to fill the opening 400, and the second filling section 620 is located on a side of the second support layer 320 facing away from the display panel 200.

Further, the filling structure 600 includes the first filling section 610 and the second filling section 620. The first filling section 610 and the second filling section 620 are connected to each other. In an embodiment, referring to FIGS. 17 and 18, the first filling section 610 is filled in the opening 400, and the second filling section 620 is located on the side of the second support layer 320 facing away from the display panel 200.

In an embodiment, the first filling section 610 can fill the opening 400 to prevent other particles (such as some particles generated during the manufacturing process) from being transported to the opening 400. The second filling section 620, which is located on the side of the second support layer 320 facing away from the display panel 200, cooperates with the first filling section 610 so as to more effectively block the transmission of particles, thereby ensuring the structural stability of the second support layer 320. The Young's modulus of the first filling section 610 and the second filling section 620 are both less than the Young's modulus of the second support layer 320; therefore, the provided filling structure 600 can still ensure stress release at the opening 400, prevent the second support layer 320 from wrinkling in the curved display region 101, and ensure the structural stability of the display module 10.

The arrangement of the second filling section in the filling structure is varied, and the details are as follows.

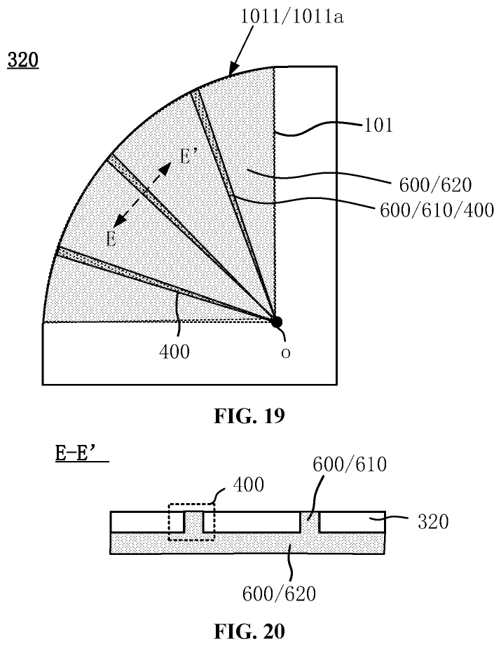

FIG. 19 is still another enlarged schematic view of a second support layer in a curved display region of FIG. 3, and FIG. 20 is a schematic sectional view taken along a section line E-E′ of FIG. 19. Referring to FIGS. 19 and 20, the second filling section 620 covers at least part of the curved display region 101 in the thickness direction of the display module 10.

Referring to FIGS. 19 and 20, the second filling section 620 may cover the entire curved display region 101 in the thickness direction of the display panel 10. By increasing the arrangement area of the second filling section 620, the wrapping effect on the curved display region 101 is improved, so as to better ensure that the filling structure 600 effectively protects the second support layer 320 provided with the opening 400. In an embodiment, on the one hand, other particles can be better prevented from interfering with the second support layer 320 and subsequent film layers; and on the other hand, the flatness of the overall structure can also be ensured.

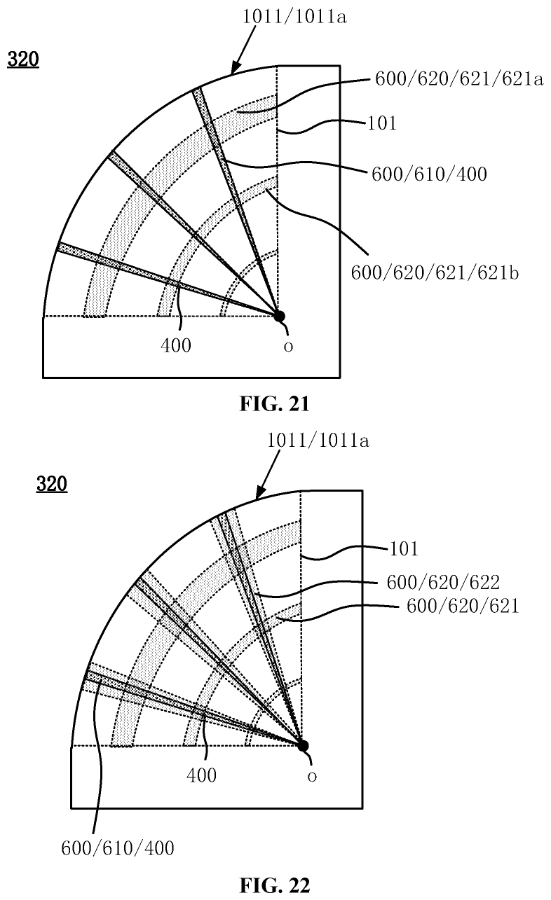

FIG. 21 is still another enlarged schematic view of a second support layer in a curved display region of FIG. 3. Referring to FIG. 21, at least the second support layer 320 is provided with multiple openings 400 at the non-linear edge 1011. The second filling section 620 includes at least one circumferential sub-section 621. An extension direction of the at least one circumferential sub-section 621 intersects an extension direction of the multiple openings 400, and the same circumferential sub-section 621 is connected to the first filling section 610 within the multiple openings 400.

In FIG. 21, the second filling section 620 includes the at least one circumferential sub-section 621. FIG. 21 illustrates, by way of example, that the second filling section 620 includes three circumferential sub-sections 621 in one curved display region 101. The specific setting number of circumferential sub-sections 621 is not specifically limited in the present application and may be adaptively adjusted according to actual requirements.

Further, referring to FIG. 21, the extension direction of the multiple openings 400 is a radial direction extending from the circle center o to the non-linear edge 1011. The extension direction of the circumferential sub-section 620 intersects the extension direction of the openings 400, that is, the circumferential sub-section 621 may be understood as a partial annular structure disposed around the circle center o. In an embodiment, as shown in FIG. 21, the same circumferential sub-section 621 is connected to the first filling sections 610 disposed in the multiple openings 400. In other words, the provided partial annular circumferential sub-section 621 overlaps the multiple openings 400, so that the circumferential sub-section 621 can connect to the first filling section 610 disposed within the opening 400. This can achieve a more stable connection between the first filling section 610 and the second filling section 620, thereby improving the protection effect of the filling structure 600 on the film layer structure, enhancing the structural stability of the display module 10 by the provided filling structure 600, and ensuring the reliability of the display module 10. Further, the circumferential sub-section 621 connects the multiple openings 400 and can apply a circumferential acting force to the openings at different positions, thereby further improving the stability of the entire support structure and the display module.

With continued reference to FIG. 21, the second filling section 620 includes multiple circumferential sub-sections 621 arranged in the extension direction of the opening 400.

Further, referring to FIG. 21, the second filling section 620 includes the multiple circumferential sub-sections 621. The circumferential sub-sections 621 are sequentially arranged in the extension direction of the opening 400. FIG. 21 illustrates, by way of example, that the curved display region 101 includes three circumferential sub-sections 621. The three circumferential sub-sections 621 are sequentially arranged in the extension direction of the opening 400.

The greater number of circumferential sub-sections 621 is provided to achieve a more stable connection between the second filling section 620 and the first filling section 610, thereby improving the protection effect of the filling structure 600 on the film layer structure, enhancing the structural stability of the display module 10 by the provided filling structure 600, and ensuring the reliability of the display module 10. Moreover, the arrangement of the multiple circumferential sub-sections 621 enables circumferential acting forces to be applied to the openings at different positions in the radial direction, thereby further improving the stability of the entire support structure and the display module.

With continued reference to FIG. 21, the multiple circumferential sub-sections 621 include a first circumferential sub-section 621a and a second circumferential sub-section 621b. The first circumferential sub-section 621a is located on a side of the second circumferential sub-section 621b facing the non-linear edge 1011. The width of the first circumferential sub-section 621a is greater than the width of the second circumferential sub-section 621b the extension direction of the opening 400.

Further, referring to FIG. 21, the second filling section 620 includes the multiple circumferential sub-sections 621. The multiple circumferential sub-sections 621 include the first circumferential sub-section 621a and the second circumferential sub-section 621b. The first circumferential sub-section 621a and the second circumferential sub-section 621b are disposed at different positions in the curved display region 101. In an embodiment, the first circumferential sub-section 621a is located on the side of the second circumferential sub-section 621b facing the non-linear edge 1011. The multiple circumferential sub-sections 621 provided in the embodiments of the present application can be finely adjusted according to their different arrangement positions, for example, in terms of dimension and other parameters, so that the provided circumferential sub-sections 621 can be better connected to the first filling section 610, and the overall structural stability of the display module 10 is ensured.

In an embodiment, as described above, in the curved display region 101, the stress generated near the non-linear edge 1011 is greater than the stress generated near the circle center o; therefore, the stress release intensity of the opening 400 near the non-linear edge 1011 is greater than the stress release intensity of the opening 400 near the circle center o. Therefore, the stress release intensity of the first filling section 610 filled in the opening 400 near the non-linear edge 1011 is also greater than the stress release intensity of the first filling section 610 near the circle center o. Therefore, in order to prevent stress from interfering with the connection stability between the first filling section 610 and the second filling section 620, the width of the first circumferential sub-section 621a in the extension direction of the opening 400 may be set to be greater than the width of the second circumferential sub-section 621b in the extension direction of the opening 400. That is, the widths of different circumferential sub-sections 621 in the extension direction of the openings 400 are adjusted according to the stress release intensity, so as to ensure the structural stability of the first filling section 610 and the second filling section 620, improve the protection effect of the filling structure 600 on the film layer structure, and further ensure the overall structural stability of the display module 10.

With continued reference to FIGS. 17 and 18, the second filling section 620 includes at least one radial sub-section 622, and the at least one radial sub-section 622 covers at least part of the at least one opening 400 in the thickness direction of the display module 10.

Further, referring to FIGS. 17 and 18, the second filling section 620 includes at least one radial sub-section 622. The setting number of radial sub-sections 622 can be adaptively adjusted according to actual requirements. FIG. 17 illustrates, by way of example, that one curved display region 101 includes three openings 400 and three radial sub-sections 622, which is not in an embodiment limited in the embodiments of the present application.

In an embodiment, referring to FIGS. 17 and 18, the radial sub-section 622 covers at least part of the opening 400 in the thickness direction of the module 10, that is, the radial sub-section 622 covers the opening 400, and this configuration, together with the first filling section 610 within the opening 400, achieves multi-directional protection of the opening 400. In this way, this can achieve a more stable connection between the first filling section 610 and the second filling section 620, thereby improving the protection effect of the filling structure 600 on the film layer structure, enhancing the structural stability of the display module 10 by the provided filling structure 600, and ensuring the reliability of the display module 10.

FIG. 22 is still another enlarged schematic view of a second support layer in a curved display region of FIG. 3. Referring to FIG. 22, at least the second support layer 320 is provided with multiple openings 400 at the non-linear edge 1011. The second filling section 620 includes at least one circumferential sub-section 621 and multiple radial sub-sections 622. The extension direction of the circumferential sub-section 621 intersects the extension direction of the opening 400, and the same circumferential sub-section 621 is connected to the first filling section 610 within the multiple openings 400. The radial sub-section 622 covers at least part of the opening 400 in the thickness direction of the display module 10. The radial sub-section 622 is connected to the circumferential sub-section 621.

Further, referring to FIG. 22, the second filling section 620 includes the at least one circumferential sub-section 621 and the multiple radial sub-sections 622. FIG. 22 illustrates, by way of example, that the second filling section 620 includes three circumferential sub-sections 621 and three radial sub-sections 622 in one curved display region 101. The specific setting number of circumferential sub-sections 621 and radial sub-sections 622 is not specifically limited in the present application and may be adaptively adjusted according to actual requirements.

Both the circumferential sub-sections 621 and the radial sub-sections 622 are provided to improve the connection stability between the first filling section 610 and the second filling section 620. Therefore, both the circumferential sub-sections 621 and the radial sub-sections 622 are disposed in the second filling section 620, so that the protection effect of the filling structure 600 on the film layer structure can be further improved, the structural stability of the display module 10 by the provided filling structure 600 can be ensured, and the reliability of the display module 10 can be ensured. In addition, the circumferential sub-sections 621 and the radial sub-sections 622 are combined to form the mesh-shaped second filling section 620, so that the second filling section 620 can provide acting forces in both the circumferential direction and the radial direction, thereby ensuring the structural stability of the second support layer 320, the support structure 300, and the entire display module 10.

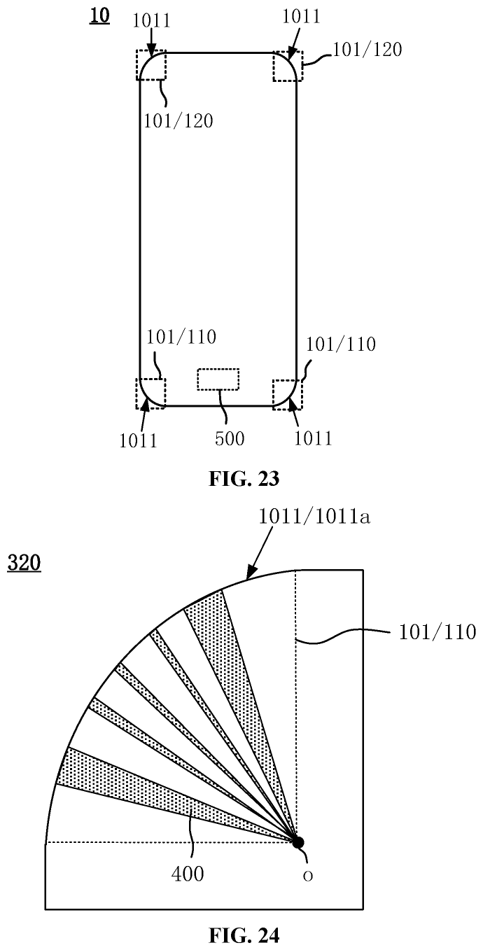

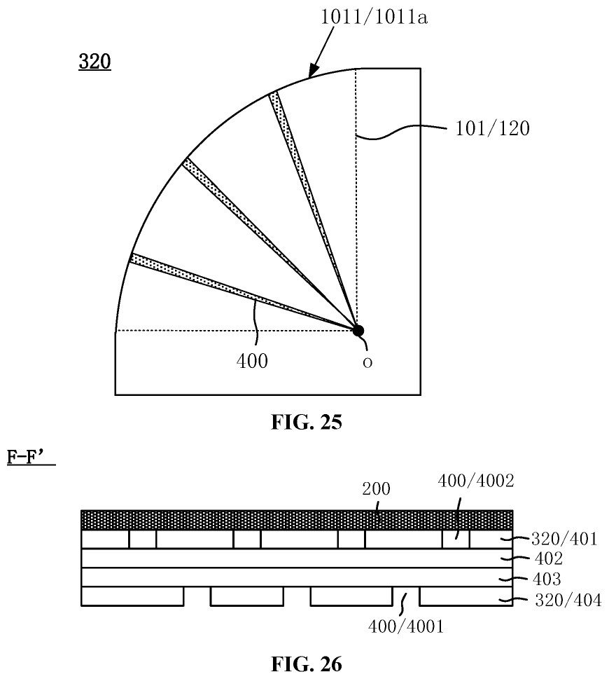

FIG. 23 is a schematic structural view of another display module according to an embodiment of the present application, FIG. 24 is an enlarged schematic view of a second support layer in a first curved display region of FIG. 23, and FIG. 25 is an enlarged schematic view of a second support layer in a second curved display region of FIG. 23. Referring to FIGS. 23 to 25, the display module 10 further includes a driver chip 500. The display module 10 includes a first curved display region 110 and a second curved display region 120. The first curved display region 110 is located on a side of the second curved display region 120 facing the driver chip 500. The distribution density of the openings 400 in the first curved display region 110 is greater than the distribution density of the openings 400 in the second curved display region 120.

Further, as shown in FIG. 23, the display module 10 further includes a driver chip 500. The provided driver chip 500 is configured to transmit relevant signals to the display panel to drive the display panel for display, thereby achieving the display function of the display module 10. In an embodiment, the arrangement of the driver chip 500 may be referred to FIG. 1 and FIG. 2.

In an embodiment, referring to FIGS. 23 to 25, the display module 10 includes the first curved display region 110 and the second curved display region 120, and the first curved display region 110 and the second curved display region 120 have differences in mounting positions. In an embodiment, the first curved display region 110 is located on the side of the second curved display region 120 facing the driver chip 500. Considering that more signal traces are provided around the first curved display region 110 on the side close to the driver chip 500, that is, the first curved display region 110 is more prone to stress concentration and bubble generation. Therefore, the distribution density of the openings 400 in the first curved display region 110 may be set to be higher. By performing a differentiated arrangement of the opening 400 in the first curved display region 110 and the opening 400 in the second curved display region 120, the stress generated in the display module 10 can be relieved by virtue of the openings 400 while ensuring the display effect of the display module 10, thereby ensuring the overall structural stability of the display module 10.

In an embodiment, referring to FIGS. 24 and 25, the distribution density of the openings 400 in the first curved display region 110 is adjusted to be greater than the distribution density of the openings 400 in the second curved display region 120. It can be seen from FIG. 24 and FIG. 25 that the difference in distribution density between the openings 400 in the first curved display region 110 and the openings 400 in the second curved display region 120 can be achieved by adjusting the setting number of the openings 400 in the first curved display region 110 to be greater than the setting number of the openings 400 in the second curved display region 120. Optionally, the difference in distribution density between the openings 400 in the first curved display region 110 and the openings 400 in the second curved display region 120 can be achieved by adjusting the setting size of the openings 400 in the first curved display region 110 to be greater than the setting size of the openings 400 in the second curved display region 120. Optionally, the difference in distribution density between the openings 400 in the first curved display region 110 and the openings 400 in the second curved display region 120 can be achieved by adjusting the setting number of the openings 400 in the first curved display region 110 to be greater than the setting number of the openings 400 in the second curved display region 120 and the setting size of the openings 400 in the first curved display region 110 to be greater than the setting size of the openings 400 in the second curved display region 120. The arrangement of the openings 400 can be adjusted in various ways and may be adaptively optimized according to actual product requirements or fabrication process requirements.

Optionally, referring to FIGS. 2 and 3, the first support layer 310 includes an adhesive layer 402 and/or a foam 403. The second support layer 320 includes a metal support layer 404 and/or an inorganic support layer 401.

In an embodiment, referring to FIG. 2, the Young's modulus of the adhesive layer 402 and the foam 403 in the support structure 300 is lower than the Young's modulus of the metal support layer 404 and the inorganic support layer 401 in the support structure 300. The Young's modulus of the first support layer 310 is less than the Young's modulus of the second support layer 320, and the first support layer 310 may be the adhesive layer 402, the foam layer 403, or a combination of the adhesive layer 402 and the foam layer 403. The second support layer 320 may be the metal support layer 404, the inorganic support layer 401, or the metal support layer 404 and/or the inorganic support layer 401. In this way, the first support layer 310 and the second support layer 320 may be selected in a variety of manners, so that the arrangement positions of the openings 400 are more flexible. Exemplarily, referring to FIG. 3, FIG. 3 illustrates, by way of example, that the first support layer 310 is the foam 403 and the second support layer 320 is the metal support layer 404.

FIG. 26 is a schematic sectional view taken along a section line F-F′ of FIG. 15. Referring to FIGS. 2, 15, and 26, the second support layer 320 includes a metal support layer 404 and an inorganic support layer 401. The metal support layer 404 is provided with at least one first-type opening 4001 at the non-linear edge 1011. The inorganic support layer 401 is provided with at least one second-type opening 4002 at the non-linear edge 1011. The first-type opening 4001 and the second-type opening 4002 are disposed in a staggered manner in the thickness direction of the display module 10.

Further, referring to FIG. 26, the metal support layer 404 and the inorganic support layer 401 may be used as the second support layer 320, that is, the opening 400 may be provided in the metal support layer 404 to release the stress, and the opening 400 may also be provided in the inorganic support layer 401 to release the stress, thereby better achieving the stress release and ensuring the overall structural stability of the display module 10.

In an embodiment, referring to FIG. 26, the metal support layer 404 is provided with the at least one first-type opening 4001 at the non-linear edge 1011, and the inorganic support layer 401 is provided with the at least one second-type opening 4002 at the non-linear edge 1011. The first-type opening 4001 and the second-type opening 4002 may be disposed in a staggered manner in the thickness direction of the display module 10. In this way, the openings 400 disposed at different film layers can be prevented from affecting the overall structural stability and flatness of the display module 10 due to overlap in the thickness direction, and the structural reliability of the display module 10 is ensured. Moreover, stress release can be achieved in more regions of the display module 10, which further improves the structural reliability of the display module 10.

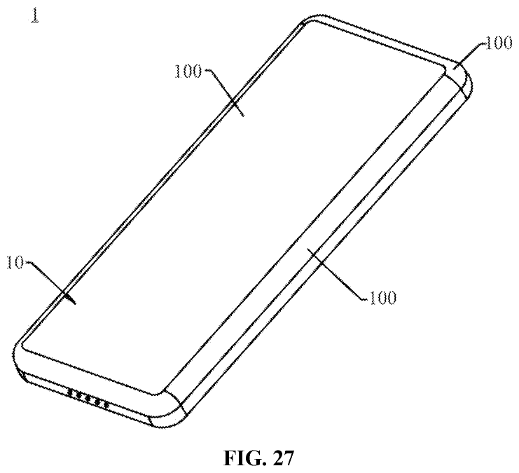

Based on the same inventive concept, the embodiments of the present application further provide a display device. FIG. 27 is a schematic structural view of a display device according to an embodiment of the present application. As shown in FIG. 27, the display device 1 includes the display module 10 described in any of the above embodiments. Therefore, the display device 1 provided in the embodiments of the present application has the corresponding beneficial effects in the above embodiments, which will not be detailed herein again. The display device 1 may be an electronic device such as a mobile phone, a computer, a smart wearable device (for example, a smart watch), or an in-vehicle display device.

Apparently, the foregoing embodiments of the present application are merely examples for clearly illustrating the present application, and are not intended to limit the embodiments of the present application. Those of ordinary skill in the art may make various obvious modifications, rearrangements, and substitutions without departing from the scope of protection of the present application. It is unnecessary and impractical to exhaust all embodiments herein. Any modifications, equivalent replacements, and improvements made within the spirit and principle of the present application shall fall within the scope of protection of the claims of the present application.

What is claimed is:

1. A display module, comprising a curved display region, wherein the curved display region comprises a non-linear edge;
the display module further comprises a display panel and a support structure disposed in a stacked manner, the support structure is located on a non-light-emitting side of the display panel, the support structure comprises a first support layer and a second support layer disposed in a stacked manner, and a Young's modulus of the second support layer is greater than a Young's modulus of the first support layer; and
at least the second support layer is provided with at least one opening at the non-linear edge, and the at least one opening extends through the second support layer in a thickness direction of the display module.

2. The display module of claim 1, wherein the non-linear edge comprises an arc-shaped edge;
at least part of the at least one opening extends to a circle center of the arc-shaped edge in a radial direction of the arc-shaped edge.

3. The display module of claim 2, wherein an opening width of the at least one opening gradually decreases in a direction from the arc-shaped edge toward the circle center.

4. The display module of claim 1, wherein at least the second support layer is provided with a plurality of openings at the non-linear edge; and
wherein the plurality of openings comprise a first opening and a second opening, and an opening width of the first opening at a position where the non-linear edge is located is greater than an opening width of the second opening at the position where the non-linear edge is located.

5. The display module of claim 4, wherein the non-linear edge comprises an arc-shaped edge, the arc-shaped edge comprises an arc-shaped starting point and an arc-shaped midpoint, a central angle corresponding to the arc-shaped edge is γ, and a central angle corresponding to an arc segment between the arc-shaped midpoint and the arc-shaped starting point is δ, wherein δ=γ/2;
the curved display region comprises a first curved sub-display region and a second curved sub-display region, the first curved sub-display region comprises the arc-shaped starting point, and the second curved sub-display region comprises the arc-shaped midpoint; and
the first opening is located in the first curved sub-display region, and the second opening is located in the second curved sub-display region, wherein the second curved sub-display region further comprises a first edge point located on the arc-shaped edge; and
wherein a central angle α corresponding to an arc segment between the first edge point and the arc-shaped midpoint satisfies 0°<α≤15°.

6. The display module of claim 4, further comprising a planar display region located on at least one side of the curved display region;
the curved display region comprises a third curved sub-display region and a fourth curved sub-display region, and the third curved sub-display region is located on a side of the fourth curved sub-display region facing the planar display region; and
a part of the first opening is disposed in the third curved sub-display region, remaining part of the first opening is disposed in the planar display region, and the second opening is disposed in the fourth curved sub-display region, wherein the non-linear edge comprises an arc-shaped edge, and the arc-shaped edge comprises an arc-shaped starting point on a side facing the planar display region;
the third curved sub-display region comprises a second edge point located on the arc-shaped edge, and the fourth curved sub-display region comprises a third edge point located on the arc-shaped edge; and
a central angle β corresponding to an arc segment between the second edge point and the arc-shaped starting point satisfies 0°<β≤15°, and a central angle θ corresponding to an arc segment between the third edge point and the arc-shaped starting point satisfies 30°≤θ≤60°.

7. The display module of claim 1, wherein at least the second support layer is provided with a plurality of openings at the non-linear edge;
the non-linear edge comprises an arc-shaped edge, the arc-shaped edge comprises an arc-shaped starting point and an arc-shaped midpoint, a central angle corresponding to the arc-shaped edge is γ, and a central angle corresponding to an arc segment between the arc-shaped midpoint and the arc-shaped starting point is δ, wherein δ=γ/2;
the curved display region comprises a first curved sub-display region and a second curved sub-display region, the first curved sub-display region comprises the arc-shaped starting point, and the second curved sub-display region comprises the arc-shaped midpoint; and
a distribution density of the openings located in the second curved sub-display region is greater than a distribution density of the openings located in the first curved sub-display region.

8. The display module of claim 1, wherein at least the second support layer is provided with a plurality of openings at the non-linear edge;
the non-linear edge comprises an arc-shaped edge, the arc-shaped edge comprises an arc-shaped starting point and an arc-shaped midpoint, a central angle corresponding to the arc-shaped edge is γ, and a central angle corresponding to an arc segment between the arc-shaped midpoint and the arc-shaped starting point is δ, wherein δ=γ/2;
the curved display region comprises a first curved sub-display region and a second curved sub-display region, the first curved sub-display region comprises the arc-shaped starting point, and the second curved sub-display region comprises the arc-shaped midpoint; and
an extension length of an opening located in the second curved sub-display region is greater than an extension length of an opening located in the first curved sub-display region.

9. The display module of claim 1, wherein a thickness of the first support layer disposed in the curved display region gradually decreases in a direction from a non-linear edge toward a center of the display module.

10. The display module of claim 9, wherein a thickness of the second support layer disposed in the curved display region gradually increases in a direction from the non-linear edge toward the center of the display module.

11. The display module of claim 1, further comprising a filling structure, wherein the filling structure at least partially fills the at least one opening and has a Young's modulus less than the Young's modulus of the second support layer.

12. The display module of claim 11, wherein the filling structure comprises a first filling section and a second filling section connected to each other; and
wherein the first filling section is configured to fill the at least one opening, and the second filling section is located on a side of the second support layer facing away from the display panel.

13. The display module of claim 12, wherein the second filling section covers at least part of the curved display region in the thickness direction of the display module.

14. The display module of claim 12, wherein at least the second support layer is provided with a plurality of openings at the non-linear edge; and
wherein the second filling section comprises at least one circumferential sub-section, an extension direction of the at least one circumferential sub-section intersects an extension direction of the plurality of openings, and a same circumferential sub-section among the at least one circumferential sub-section is connected to the first filling section within the plurality of openings.

15. The display module of claim 14, wherein the second filling section comprises a plurality of circumferential sub-sections arranged in an extension direction of the plurality of openings,
wherein the plurality of circumferential sub-sections comprise a first circumferential sub-section and a second circumferential sub-section, and the first circumferential sub-section is located on a side of the second circumferential sub-section facing the non-linear edge; and
wherein a width of the first circumferential sub-section is greater than a width of the second circumferential sub-section in the extension direction of the plurality of openings.

16. The display module of claim 12, wherein the second filling section comprises at least one radial sub-section, and the at least one radial sub-section covers at least part of the at least one opening in the thickness direction of the display module.

17. The display module of claim 12, wherein at least the second support layer is provided with a plurality of openings at the non-linear edge;
the second filling section comprises at least one circumferential sub-section and a plurality of radial sub-sections, an extension direction of the at least one circumferential sub-section intersects an extension direction of the plurality of openings, a same circumferential sub-section among the at least one circumferential sub-section is connected to the first filling section within the plurality of openings, and each of the plurality of radial sub-section covers at least part of the plurality of openings in the thickness direction of the display module; and
each of the plurality of radial sub-sections is connected to a respective one of the at least one circumferential sub-section.

18. The display module of claim 1, further comprising a driver chip;
the display module comprises a first curved display region and a second curved display region, and the first curved display region is located on a side of the second curved display region facing the driver chip; and
a distribution density of the openings located in the first curved display region is greater than a distribution density of the openings located in the second curved display region.

19. The display module of claim 1, wherein the first support layer comprises at least one of an adhesive layer or a foam; and
the second support layer comprises at least one of a metal support layer or an inorganic support layer,
wherein the second support layer comprises the metal support layer and the inorganic support layer;
the metal support layer is provided with at least one first-type opening at the non-linear edge, and the inorganic support layer is provided with at least one second-type opening at the non-linear edge; and
the at least one first-type opening and the at least one second-type opening are disposed in a staggered manner in the thickness direction of the display module.

20. A display device comprising a display module, wherein the display module comprises a curved display region, wherein the curved display region comprises a non-linear edge;
the display module further comprises a display panel and a support structure disposed in a stacked manner, the support structure is located on a non-light-emitting side of the display panel, the support structure comprises a first support layer and a second support layer disposed in a stacked manner, and a Young's modulus of the second support layer is greater than a Young's modulus of the first support layer; and
at least the second support layer is provided with at least one opening at the non-linear edge, and the at least one opening extends through the second support layer in a thickness direction of the display module.
